(19) United States
(12) Patent Application Publication
(10) Pub. No.: US 2023/0016088 A1
(43) Pub. Date: Jan. 19, 2023

(54) SEMICONDUCTOR STRUCTURE AND FABRICATION METHOD THEREOF

(71) Applicant: CHANGXIN MEMORY TECHNOLOGIES, INC., Hefei (CN)

(72) Inventors: Yexiao YU, Hefei (CN); Zhongming LIU, Hefei (CN)

(21) Appl. No.: 17/953,335

(22) Filed: Sep. 27, 2022

Related U.S. Application Data
(63) Continuation of application No. PCT/CN2022/096474, filed on May 31, 2022.

(30) Foreign Application Priority Data
Aug. 16, 2021 (CN) 202110936349.6

(51) Int. Cl. H01L 27/108; G11C 5/06

(52) U.S. Cl. CPC H01L 27/10888; H01L 27/10855; H01L 27/10873; H01L 27/10885; H01L 27/10814; H01L 27/10891; G11C 5/063

(57) ABSTRACT

An embodiment provides a method for fabricating a semiconductor structure. The method includes: providing a semiconductor substrate having an active area, the active area including a first active area and a second active area isolated from each other; forming a bitline contact groove on the semiconductor substrate, the bitline contact groove exposing the first active area; forming an etch stop layer covering a sidewall of the bitline contact groove, the etch stop layer exposing a partial area of the first active area at a bottom of the bitline contact groove; etching the semiconductor substrate by using the etch stop layer as a mask to form a pit at the bottom of the bitline contact groove, the pit being at least partially positioned in the first active area; removing the etch stop layer; forming a bitline structure; and forming a conductive plug electrically connected to the second active area.

### CROSS-REFERENCE TO RELATED APPLICATION

The present disclosure is a continuation of PCT/CN2022/096474, filed on May 31, 2022, which claims priority to Chinese Patent Application No. 202110936349.6, titled “METHOD FOR FABRICATING SEMICONDUCTOR STRUCTURE” and filed on Aug. 16, 2021, the entire contents of which are incorporated herein by reference.

### TECHNICAL FIELD

The present disclosure relates to the field of semiconductor technology, and more particularly, to a semiconductor structure and a fabrication method thereof.

### BACKGROUND

Development of dynamic memory pursues high speed, high integration density, and low power consumption, etc. However, with the miniature of structure sizes of semiconductor devices, especially for DRAM (dynamic random access memory) with a critical size smaller than 17 nm, its drive current (magnitude of current between a recessed transistor and a bitline structure) is smaller, which directly limits electrical performance and storage efficiency of the dynamic memory.

It is to be noted that the information disclosed in the above background art section is only for enhancement of understanding of the background of the present disclosure, and therefore may include information that does not constitute the prior art that is already known to a person of ordinary skill in the art.

### SUMMARY

The present disclosure provides a semiconductor structure and a fabrication method thereof.

According to an aspect of the present disclosure, there is provided a method for fabricating a semiconductor structure, including:

providing a semiconductor substrate having an active area; the active area including a first active area and a second active area isolated from each other;

forming a bitline contact groove on the semiconductor substrate, the bitline contact groove exposing the first active area;

forming an etch stop layer covering a sidewall of the bitline contact groove, the etch stop layer exposing a partial area of the first active area at a bottom of the bitline contact groove;

etching the semiconductor substrate by using the etch stop layer as a mask to form a pit at the bottom of the bitline contact groove, the pit being at least partially positioned in the first active area;

removing the etch stop layer;

forming a bitline structure, a bitline lead of the bitline structure filling up the pit; and

forming a conductive plug, the conductive plug being electrically connected to the second active area.

According to another aspect of the present disclosure, there is provided a semiconductor structure including a semiconductor substrate, a bitline structure and a conductive plug, where the semiconductor substrate has an active area, which includes a first active area and a second active area isolated from each other. The semiconductor substrate is provided with a bitline contact groove overlapped with the first active area, and a pit at least partially positioned in the first active area is provided at a bottom of the bitline contact groove. The bitline structure includes a bitline lead configured for electric conduction, the bitline lead fills up the pit and is electrically connected to the first active area in the bitline contact groove. The conductive plug is electrically connected to the second active area.

It is to be understood that the above general description and the detailed description below are merely exemplary and explanatory, and do not limit the present disclosure.

### BRIEF DESCRIPTION OF THE DRAWINGS

The accompanying drawings herein are incorporated in and constitute a part of this specification, illustrate embodiments conforming to the present disclosure and, together with the specification, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 is a schematic top view of shallow trench isolation on a semiconductor substrate according to an embodiment of the present disclosure;

FIG. 2 is a schematic top view of the shallow trench isolation structure and a wordline structure on the semiconductor substrate according to an embodiment of the present disclosure;

FIG. 3 is a schematic cross-sectional structural diagram of a PQ position in FIG. 1;

FIG. 4 is a schematic cross-sectional structural diagram of a PQ position in FIG. 2;

FIG. 5 is a schematic structural diagram of a first mask material layer formed on a semiconductor substrate according to an embodiment of the present disclosure;

FIG. 6 is a schematic top view of s position of the first mask layer on the semiconductor substrate according to an embodiment of the present disclosure;

FIG. 7 is a schematic structural diagram of a first mask layer formed on the semiconductor substrate according to an embodiment of the present disclosure;

FIG. 8 is a schematic structural diagram of a bitline contact groove formed according to an embodiment of the present disclosure;

FIG. 9 is a schematic structural diagram of an etch stop material layer formed according to an embodiment of the present disclosure;

FIG. 10 is a schematic structural diagram of an etch stop layer formed according to an embodiment of the present disclosure;

FIG. 11 is a schematic structural diagram of a pit formed according to an embodiment of the present disclosure;

FIG. 12 is a schematic structural diagram of an etch stop layer removed according to an embodiment of the present disclosure;

FIG. 13 is a schematic structural diagram of a polysilicon filling material layer formed according to an embodiment of the present disclosure;

FIG. 14 is a schematic structural diagram of the polysilicon filling material layer etched back according to an embodiment of the present disclosure;

FIG. 15 is a schematic structural diagram of the first mask layer removed according to an embodiment of the present disclosure;

FIG. 16 is a schematic structural diagram of a bitline conductive material layer and a bitline insulation cap material layer formed according to an embodiment of the present disclosure;

FIG. 17 is a schematic structural diagram of a bitline insulation cap layer and a bitline second conductive layer formed according to an embodiment of the present disclosure;

FIG. 18 is a schematic structural diagram of a bitline first conductive layer and a polysilicon filling layer formed according to an embodiment of the present disclosure;

FIG. 19 is a schematic structural diagram of an insulation filling material layer formed according to an embodiment of the present disclosure;

FIG. 20 is a schematic structural diagram of an insulation filling layer formed according to an embodiment of the present disclosure;

FIG. 21 is a schematic structural diagram of a bitline first insulation material layer formed according to an embodiment of the present disclosure;

FIG. 22 is a schematic structural diagram of a bitline first insulation layer formed according to an embodiment of the present disclosure;

FIG. 23 is a schematic structural diagram of a bitline second insulation layer formed according to an embodiment of the present disclosure;

FIG. 24 is a schematic structural diagram of a plug hole formed according to an embodiment of the present disclosure;

FIG. 25 is a schematic structural diagram of a conductive plug formed according to an embodiment of the present disclosure;

FIG. 26 is a schematic structural diagram of an electrode material layer formed according to an embodiment of the present disclosure;

FIG. 27 is a schematic structural diagram of a transfer electrode formed according to an embodiment of the present disclosure;

FIG. 28 is a schematic structural diagram of an isolation material layer formed according to an embodiment of the present disclosure; and

FIG. 29 is a schematic flowchart of a method for fabricating a semiconductor structure according to an embodiment of the present disclosure;

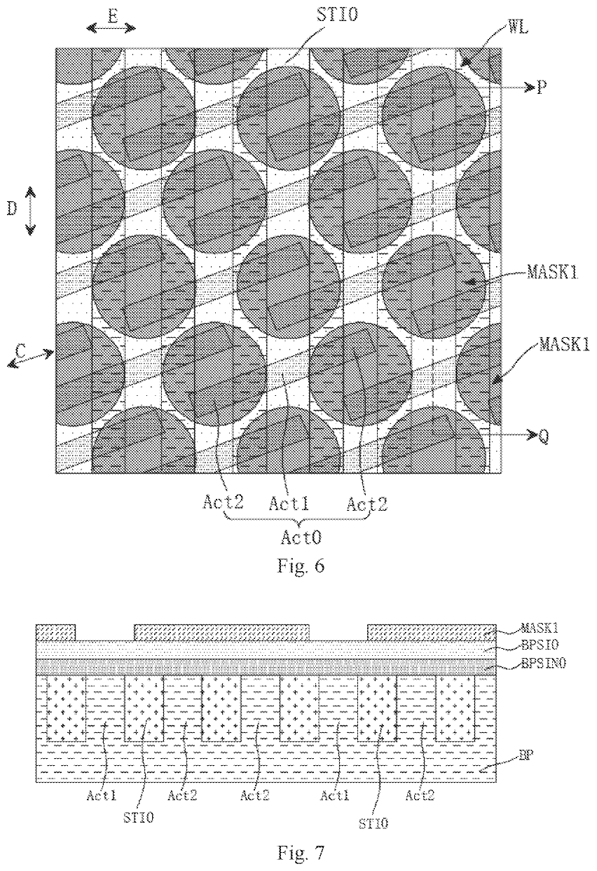

where section cutting positions in FIGS. 7 to 28 are the positions shown by the section cutting line PQ in FIG. 6.

### REFERENCE NUMERALS IN THE ACCOMPANYING DRAWINGS

BP—semiconductor substrate; STI—shallow trench isolation; STI0—shallow trench isolation structure; Act0—active area; Act1—first active area; Act2—second active area; WL—wordline structure; BPSIN—substrate insulation layer; BPSI—substrate etching positioning layer; MASK1—first mask layer; MASK2—second mask layer; MASK3—third mask layer; ESL—etch stop layer; BL—bitline structure; BLL—bitline lead; BLL1—polysilicon filling layer; BLL2—bitline conductive layer; BLL21—bitline first conductive layer; BLL22—bitline second conductive layer; BLL3—bitline insulation cap layer; BLF—insulation filling layer; BLF1—insulation first filling layer; BLF2—insulation second filling layer; BLD—bitline insulation layer; BLD1—bitline first insulation layer; BLD2—bitline second insulation layer; PLUG—conductive plug; PAD—transfer electrode; PAD0—electrode material layer; PAD1—isolation material layer; BLGR—bitline contact groove; BLPIT—pit; and HOLE0—plug hole.

### DETAILED DESCRIPTION

Exemplary embodiments will now be described more comprehensively with reference to the accompanying drawings. However, the exemplary embodiments may be carried out in various manners, and shall not be interpreted as being limited to the embodiments set forth herein; instead, providing these embodiments will make the present disclosure more comprehensive and complete, and will fully convey the conception of the exemplary embodiments to those skilled in the art. Throughout the drawings, similar reference signs indicate the same or similar structures, and thus their detailed description will be omitted. In addition, the accompanying drawings are merely exemplary illustration of the present disclosure, and are not necessarily drawn to scale.

Although this specification employs relativity terms such as “above” and “below” to describe a relative relation between one component and another component of icons, these terms are merely for convenience of this specification, for example, the directions of the examples in the accompanying drawings. It is to be understood that when the apparatus of the icon are turned upside down, components described as “above” will become components described as “below”. When a certain structure is “above” other structures, it likely means that the certain structure is integrally formed on the other structures, or the certain structure is “directly” arranged on the other structures, or the certain structure is “indirectly” arranged on the other structures by means of another structure.

The terms “one”, “a”, “said”, “the” and “at least one” may be intended to indicate presence of one or more elements/constituent parts, etc. The terms “comprising” and “having” are inclusive and therefore specify the presence of other elements/constituent parts or the like in addition to the elements/constituent parts listed out. The terms “first”, “second” and “third” or the like are merely for marker purposes, and do not impose numerical limitations on objects thereof.

The present disclosure provides a semiconductor structure and a fabrication method thereof. Referring to FIG. 29, the method for fabricating a semiconductor structure provided by the present disclosure includes:

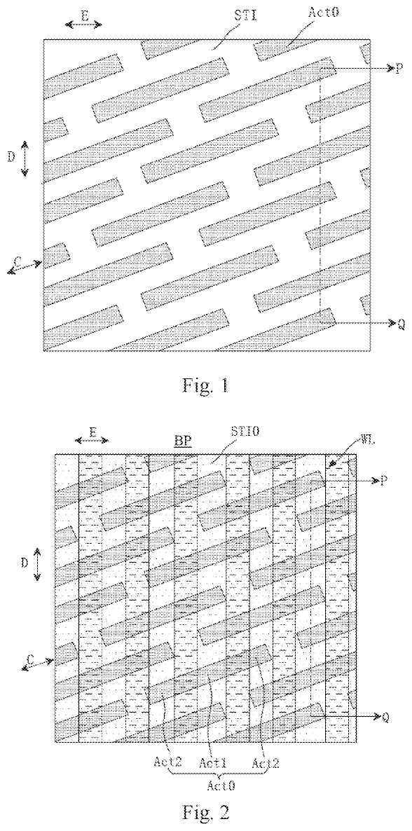

Step S110, referring to FIG. 2, providing a semiconductor substrate BP having an active area Act0, where the active area Act0 includes a first active area Act1 and a second active area Act2 isolated from each other;

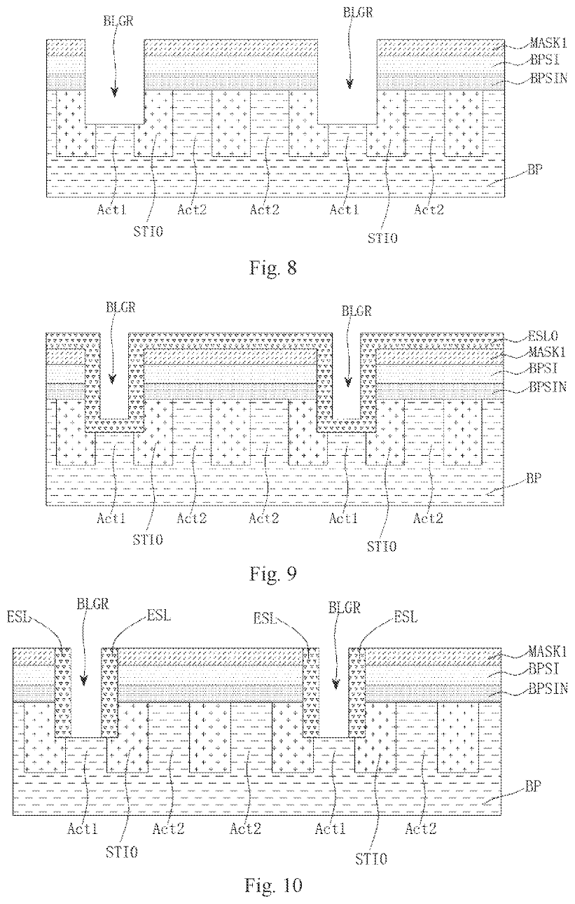

Step S120, referring to FIG. 8, forming a bitline contact groove BLGR on the semiconductor substrate BP, where the bitline contact groove BLGR exposes the first active area Act1;

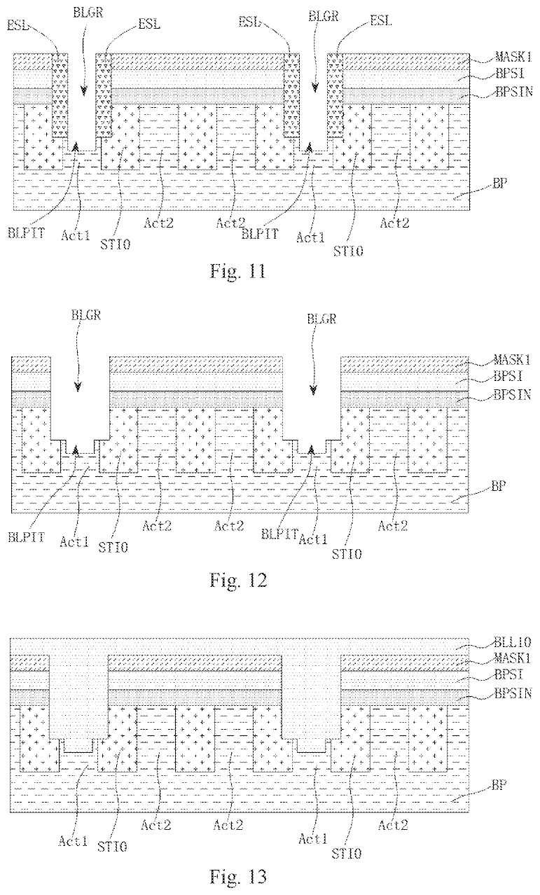

Step S130, referring to FIG. 10, forming an etch stop layer ESL covering a sidewall of the bitline contact groove BLGR, where the etch stop layer ESL exposes a partial area of the first active area Act1 at a bottom of the bitline contact groove BLGR;

Step S140, referring to FIG. 11, the semiconductor substrate BP is etched by using the etch stop layer ESL as a mask to form a pit BLPIT at the bottom of the bitline contact groove BLGR, where the pit BLPIT is at least partially positioned in the first active area Act1;

Step S150, referring to FIG. 12, removing the etch stop layer ESL;

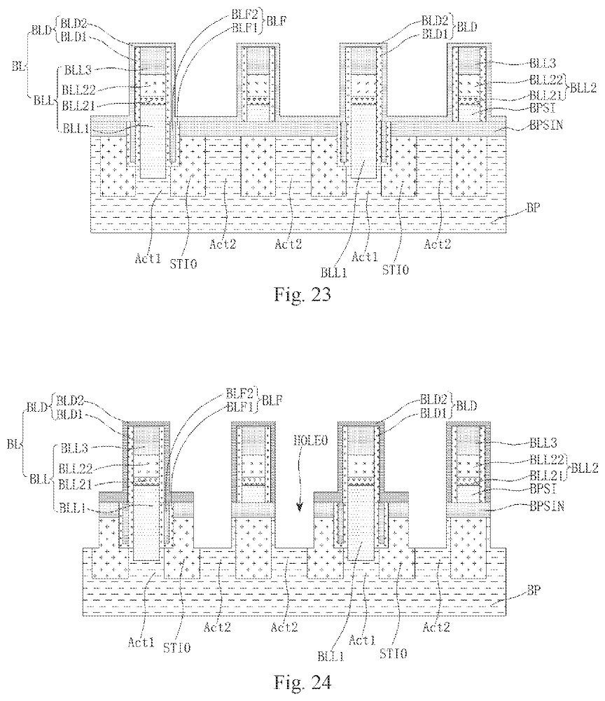

Step S160, referring to FIG. 23, forming a bitline structure BL, where a bitline lead BLL of the bitline structure BL fills up the pit BLPIT; and

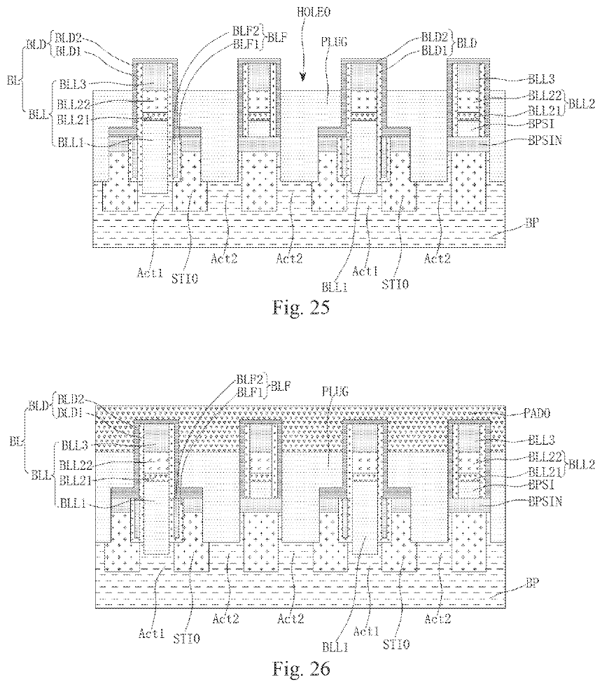

Step S170, referring to FIG. 25, forming a conductive plug PLUG electrically connected to the second active area Act2.

According to the method for fabricating a semiconductor structure provided by the present disclosure, after the bitline contact groove BLGR is formed, a pit BLPIT is also formed at the bottom of the bitline contact groove BLGR. When forming a bitline lead BLL, the bitline lead BLL may fill up the pit BLPIT, to increase a contact area between the bitline lead BLL and the first active area Act1, and increase speed of charge transfer between the bitline lead BLL and the first active area Act1, such that limitations of the speed of charge transfer on the semiconductor structure can be avoided, and thus performance of a semiconductor device can be improved.

According to the method for fabricating a semiconductor structure provided by the present disclosure, the formed semiconductor structure has a semiconductor substrate BP, a bitline structure BL, and a conductive plug PLUG. The semiconductor substrate BP has an active area Act0, which includes a first active area Act1 and a second active area Act2 isolated from each other. The semiconductor substrate BP is provided with a bitline contact groove BLGR overlapped with the first active area Act1, and a pit BLPIT at least partially positioned in the first active area Act1 is provided at a bottom of the bitline contact groove BLGR. The bitline structure BL includes a bitline lead BLL configured for electric conduction, and the bitline lead BLL fills up the pit BLPIT and is electrically connected to the first active area Act1 in the bitline contact groove BLGR. The conductive plug PLUG is electrically connected to the second active area Act2. The semiconductor structure of the present disclosure may be fabricated by the above-mentioned fabrication method, and thus has the same or similar technical effects, and detailed descriptions thereof are omitted in the present disclosure.

Hereinafter, principles, details and effects of the method for fabricating a semiconductor structure provided by the present disclosure will be further explained and illustrated in conjunction with the accompanying drawings.

In Step S110, a semiconductor substrate BP may be provided. Referring to FIG. 2, the semiconductor substrate BP is buried with a recessed transistor and a wordline structure WL, where the wordline structures WL may be connected to a gate of the recessed transistor or may be partially reused as the gate of the recessed transistor.

A material of the semiconductor substrate BP may be selected from Si, Ge, SiGe, SiC, SiGeC, InAs, GaAs, InP or other group-IIIN compound semiconductors. In some embodiments, the material of the semiconductor substrate BP also includes multilayer structures comprising these semiconductors, etc., or includes silicon on insulator (SOI), strained silicon on insulator (SSOI), strained silicon—germanium-on-insulator (S—SiGeOI), silicon-germanium on insulator (SiGeOI), and germanium on insulator (GeOI), etc. The semiconductor substrate BP may also be doped, for example, partially lightly doped to form a channel of the recessed transistor, and partially heavily doped such that a source and a drain of the recessed transistor can be electrically connected to the bitline structure BL and the conductive plug PLUG.

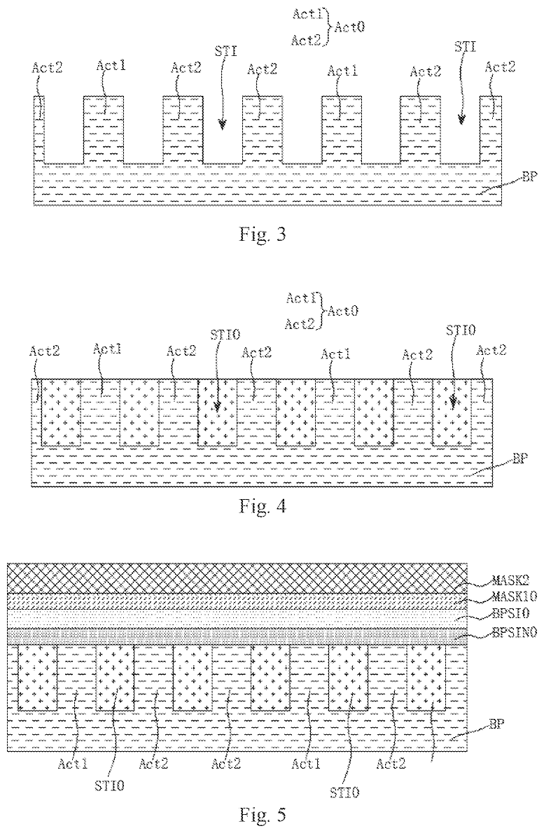

Referring to FIG. 1 and FIG. 3, the semiconductor substrate BP is provided with a shallow trench isolation STI such that a plurality of independent active areas Act0 are formed on the semiconductor substrate BP. Referring to FIG. 2 and FIG. 4, the STI may be filled with an isolation medium to form a shallow trench isolation structure STI0. For example, the STI may be filled with a dielectric medium such as silicon oxide to serve as the isolation medium. Referring to FIG. 1, in an embodiment of the present disclosure, each of the plurality of active areas Act0 is arranged into a plurality of active area columns extending along a first direction C and parallel to each other, where any one of the plurality of active area columns may include a plurality of active areas Act0, and an extension direction of the plurality of active areas Act0 is the first direction C.

In some embodiments, the semiconductor substrate BP is further provided with a wordline trench extending along a second direction D, where an angle formed between the second direction D and the first direction C may be less than 90°; and the wordline structure WL is buried in the wordline trench. Referring to FIG. 2, the wordline trench sequentially penetrates through the shallow trench isolation structure STI0 and the active area Act0 along the second direction D, and exposes the semiconductor substrate BP in the active area Act0. The active area Act0 may be divided, by the wordline trench, into a first active area Act1 and a second active area Act2 isolated from each other, where the first active area Act1 is electrically connected to the bitline lead BLL, and the second active area Act2 is electrically connected to the conductive plug PLUG. In some embodiments, dosage of dopants on a surface of the semiconductor substrate BP exposed by the wordline trench may also be adjusted. For example, by ion implantation and other methods, the dosage of dopants at the bottom of the wordline trench is increased or ions of opposite types are implanted, and next a threshold voltage of the recessed transistor is adjusted. Within the wordline trench, there may be a gate dielectric layer covering a sidewall of the wordline trench and a wordline on an inner side of the gate dielectric layer. The gate dielectric layer in the active area Act0 may serve as a gate insulation layer of the recessed transistor, and the wordline may be partially reused as the gate of the recessed transistor. It is to be understood that the gate dielectric layer may be a layer of insulation material, or may be a composite of multilayer insulation materials, and may also cover air gaps in the multilayer insulation materials, which is not limited in the present disclosure. In the active area Act0, a part of the semiconductor substrate BP corresponding to the wordline may serve as the channel of the recessed transistor, and a part of the semiconductor substrate BP connected to the channel may serve as the source and the drain of the recessed transistor. The wordline trench may also be filled with an insulation material to form a dielectric cap, where the dielectric cap covers the wordline such that the wordline is buried in the semiconductor substrate BP. In some embodiments, an insulation material may also be provided on the surface of the semiconductor substrate BP to form a protective layer, which covers the semiconductor substrate BP and protects the active area Act0. In an embodiment of the present disclosure, a material of the protective layer may be silicon nitride or silicon oxide.

In some embodiments, the surface of the semiconductor substrate BP may also be heavily doped to ensure that the source and the drain of the recessed transistor have good conductivity, thereby ensuring that the bitline structure BL and the conductive plug PLUG can be electrically connected to the source and the drain of the recessed transistor.

In an embodiment of the present disclosure, along the second direction D, every three columns of active area columns are periodically arranged; and along a third direction E perpendicular to the second direction D and positioned within a plane in the semiconductor substrate BP, the plurality of active area columns are periodically arranged. That is, in the same active area column, sum of a length of each of the plurality of active areas Act0 and a distance between two adjacent active areas Act0 in the same active area column is defined as a preset size. In two adjacent active area columns, after a pattern of one active area column is translated to the other active area column adjacent to the former one along the second direction D, the translated pattern of the active area column may be translated along a concrete direction in the first direction C by one third of the preset size, such that the translated pattern is overlapped with a pattern of the active area Act0 of the adjacent active area column. In two adjacent active area columns, after a pattern of one active area column is translated to the adjacent active area column along the third direction E, the translated pattern of the active area column is overlapped with a pattern of the active area Act0 of this adjacent active area column.

In an embodiment of the present disclosure, any one active area Act0 passes through two wordline trenches, such that two wordline structures WL pass through this active area Act0. In this way, from a top view, this active area Act0 is divided by the two wordline structures WL into a first contact region and second contact regions, where the first contact region is positioned between the two wordline structures WL penetrating through this active area Act0, number of the second contact regions is two, and the two second contact regions are positioned on two sides of the first contact region, respectively. In a further embodiment, a part of the active area Act0 positioned in the first contact region may be used as the first active area Act1, and a part of the active area Act0 positioned in the second contact region may be used as the second active area Act2.

In some embodiments, the semiconductor substrate BP may be fabricated by the following steps.

In Step S210, a semiconductor substrate BP is provided, where the semiconductor substrate BP may be a P-type lightly-doped single crystal silicon substrate or an N-type lightly-doped single crystal silicon substrate.

In Step S220, a shallow trench isolation STI is formed on the semiconductor substrate BP to isolate a plurality of independent active areas Act0 from the surface of the semiconductor substrate BP. Any one of the plurality of active areas Act0 extends along the first direction C.

In Step S230, a dielectric medium is filled in the shallow trench isolation STI to form a shallow trench isolation structure STI0, where the dielectric medium may be silicon oxide.

In Step S240, a wordline trench extending along the second direction D is formed by etching on the semiconductor substrate BP, where the wordline trench sequentially penetrates through the shallow trench isolation structure STI0 and each of the plurality of active areas Act0.

In Step S250, a gate dielectric layer covering a sidewall of the wordline trench is formed, and a conductive structure is filled in an inner side of the gate dielectric layer to form a wordline.

In Step S260, the dielectric medium is filled in the wordline trench to form a dielectric cap covering the wordline, thereby obtaining the wordline structure WL.

In this way, in the active area Act0, the wordline may be partially reused as the gate of the recessed transistor, the gate dielectric layer may be partially reused as the gate insulation layer of the recessed transistor, and a part of the semiconductor substrate BP adjacent to the wordline may be used as the channel of the recessed transistor. Both the recessed transistor and the wordline are buried in the semiconductor substrate BP.

It is to be understood that in the method for fabricating a semiconductor structure provided by the present disclosure, with the progress of each fabrication process, corresponding intermediate products may be obtained after each fabrication process, and these intermediate products are all gradually formed based on the semiconductor substrate BP of the present disclosure. In the present disclosure, these intermediate products are defined as base substrates. It is to be understood that all operations on the base substrates are performed on a side of the base substrates away from the semiconductor substrate BP.

In Step S120, a bitline contact groove BLGR may be formed on the semiconductor substrate BP, where the bitline contact groove BLGR exposes the first active area Act1.

In some embodiments, Step S120 may be implemented by the following steps.

In Step S210, referring to FIG. 6 and FIG. 7, a first mask layer MASK1 (represented by a gray circular shade in FIG. 6) is formed on the semiconductor substrate BP, where the first mask layer MASK1 covers the second active area Act2 and exposes the first active area Act1.

In Step S220, referring to FIG. 8, the semiconductor substrate BP is patterned using the first mask layer MASK1 as a mask to form the bitline contact groove BLGR exposing the first active area Act1.

In some embodiments, in Step S210, a first mask material layer MASK10 and a second mask layer MASK2 may be sequentially formed on the surface of the base substrate. Next, the first mask material layer MASK10 is patterned using the second mask layer MASK2 as a mask to form the first mask layer MASK1. It is to be understood that after the first mask layer MASK1 is formed, the residual second mask layer MASK2 may be removed, or the residual second mask layer MASK2 may also be used, together with the first mask layer MASK1, as a mask for the semiconductor substrate BP to form the bitline contact groove BLGR.

In some embodiments, a material of the first mask layer MASK1 may be silicon oxide.

In some embodiments, referring to FIG. 5, before the first mask material layer MASK10 is formed, a substrate insulation material layer BPSIN0 may also be covered on the surface of the base substrate to ensure that the recessed transistor and the wordline structure WL are buried in the semiconductor substrate Bottom BP.

The substrate insulation material layer BPSIN0 may be a layer of inorganic insulation material, or may be multilayered inorganic insulation materials stacked up. For example, in an embodiment of the present disclosure, a silicon oxide layer and a silicon nitride layer may be sequentially formed on the surface (a side configured for arranging the bitline structure BL) of the semiconductor substrate BP, where the silicon oxide layer and the silicon nitride layer stacked up may be used as the substrate insulation material layer BPSIN0 in this embodiment. In another embodiment of the present disclosure, a silicon nitride layer may be formed on the surface (a side configured for arranging the bitline structure BL) of the semiconductor substrate BP, where the silicon nitride layer may be used as the substrate insulation material layer BPSIN0 in this embodiment. It is to be understood that in other embodiments of the present disclosure, other inorganic insulation materials or other stacking manners may also be employed to form the required substrate insulation material layer BPSIN0.

In some embodiments of the present disclosure, referring to FIG. 5, before the first mask material layer MASK10 is formed, a substrate etching positioning material layer BPSIN0 may also be formed on an upper surface (the surface away from the recessed transistor) of the substrate insulation material layer BPSIN0, to facilitate patterning the first mask material layer MASK10 and avoid damage to the substrate insulation material layer BPSIN0 and the semiconductor substrate BP during patterning the first mask material layer MASK10.

In an embodiment of the present disclosure, a material of the substrate etching positioning material layer BPSI0 is different from that of the first mask material layer MASK10, such that the substrate etching positioning material layer BPSI0 can play a role of etch stop during patterning the first mask material layer MASK10. In an embodiment of the present disclosure, the material of the substrate etching positioning material layer BPSI0 may be silicon, for example, monocrystalline silicon, polycrystalline silicon, or amorphous silicon.

In Step S220, referring to FIG. 8, the semiconductor substrate BP may be patterned using the first mask layer MASK1 as a mask to form the bitline contact groove BLGR exposing the first active area Act1. In some embodiments, the semiconductor substrate BP may be etched by using the first mask layer MASK1 as a mask to form the bitline contact groove BLGR at a position not covered by the first mask layer MASK1. Correspondingly, a position of the semiconductor substrate BP covered by the first mask layer MASK1 is still covered by the first mask layer MASK1, thereby ensuring that the second active area Act2 is not exposed.

Referring to FIG. 6, according to the position of the first mask layer MASK1, after the first active areas Act1 are exposed, adjacent first active areas Act1 are isolated by the shallow trench isolation structure STI0 or the wordline structure WL, such that each of the first active areas Act1 remains isolated.

In some embodiments, referring to FIG. 8, when the substrate insulation material layer BPSIN0 and the substrate etching positioning material layer BPSI0 are provided between the semiconductor substrate BP and the first mask layer MASK1, in Step S220, the bitline contact groove BLGR penetrates through the substrate insulation material layer BPSIN0 and the substrate etching positioning material layer BPSI0 and extends into the semiconductor substrate BP to expose the first active area Act1. In this way, the substrate insulation material layer BPSIN0 and the substrate etching positioning material layer BPSI0 are respectively patterned into the substrate insulation layer BPSIN and the substrate etching positioning layer BPSI in Step S220. In some embodiments, Step S130 may be implemented by Steps S310 and S320 as below:

Step S310, referring to FIG. 9, forming an etch stop material layer ESL0 covering a surface of the first mask layer MASK1, the sidewall of the bitline contact groove BLGR and the bottom of the bitline contact groove BLGR, a part of the etch stop material layer ESL0 at the bottom of the bitline contact groove BLGR being at least partially overlapped with the first active area Act1; and

Step S320, referring to FIG. 10, patterning the etch stop material layer ESL0 to remove the part of the etch stop material layer ESL0 positioned at the bottom of the bitline contact groove BLGR, to form the etch stop layer ESL covering the sidewall of the bitline contact groove BLGR.

In Step S310, a material of the etch stop material layer ESL0 is different from that of the first active area Act1, such that the etch stop material layer ESL0 and the first active area Act1 may be selectively etched under different etching conditions. In an embodiment of the present disclosure, the material of the etch stop material layer ESL0 may be titanium nitride. Further, titanium nitride is deposited by atomic layer deposition to form the etch stop material layer ESL0.

Of course, in other embodiments of the present disclosure, the material of the etch stop material layer ESL0 may also be other materials, such as metal materials and so on. Correspondingly, when forming the etch stop material layer ESL0, other deposition methods such as chemical vapor deposition (CVD) may also be used, such that the etch stop material layer ESL0 can cover the sidewall of the bitline contact groove BLGR.

In Step S320, referring to FIG. 10, the etch stop material layer ESL0 may be etched and patterned to be the etch stop layer ESL. During the etching process, the part of the etch stop material layer ESL0 positioned at the bottom of the bitline contact groove BLGR may be removed, to form the etch stop layer ESL covering the sidewall of the bitline contact groove BLGR. In this way, at least a partial area of the first active area Act1 at the bottom of the bitline contact groove BLGR is exposed by the etch stop layer ESL. In this way, in Step S140, the first active area Act1 exposed by the etch stop layer ESL may be selectively etched to form the pit BLPIT at the bottom of the bitline contact groove BLGR.

Referring to FIG. 10, in some embodiments, during patterning the etch stop material layer ESL0, a part of the etch stop material layer ESL0 positioned on the surface of the first mask layer MASK1 may also be removed.

In an embodiment of the present disclosure, the etch stop material layer ESL0 may be patterned by dry etching. In this way, the part of the etch stop material layer ESL0 positioned on the surface of the first mask layer MASK1 and the part of the etch stop material layer ESL0 positioned at the bottom of the bitline contact groove BLGR may be effectively etched, without causing obvious damage or etching to the part of the etch stop material layer ESL0 positioned on the sidewall of the line contact groove BLGR. In this way, the remaining part of the etch stop material layer ESL0 covers the sidewall of the bitline contact groove BLGR to serve as the etch stop layer ESL of the present disclosure.

In Step S140, referring to FIG. 11, the first active area Act1 may be etched by using the etch stop layer ESL as a mask to form the pit BLPIT at the bottom of the bitline contact groove BLGR. That is, the semiconductor substrate BP exposed by the etch stop layer ESL may be selectively etched in the bitline contact groove BLGR, such that the pit BLPIT is formed on a part of the bitline contact groove BLGR not protected by the etch stop layer ESL. Referring to FIG. 11, the pit BLPIT is at least partially positioned in the first active area Act1. Arrangement of the pit BLPIT increases the surface of the first active area Act1, thereby increasing the contact area between the first active area Act1 and the bitline lead BLL, and increasing a speed of charge exchange between the first active area Act1 and the bitline lead BLL. In this way, a rate of charge transfer between the recessed transistor and the bitline structure BL may be increased, a data writing or reading speed of the semiconductor structure may be increased, and thus the performance of the semiconductor structure may be improved.

In some embodiments of the present disclosure, a depth of the bitline contact groove BLGR is 3 to 4 times of that of the pit BLPIT. In this way, a surface area of the first active area Act1 may be increased as much as possible to improve the performance of the semiconductor structure, and collapse of the pit BLPIT due to its too large depth may be prevented.

In the present disclosure, a size of the bitline lead BLL along an extension direction of the wordline structure WL is a first size, and the depth of the pit is a second size. In some embodiments, the second size is 0.5 to 2 times of the first size. For example, the second size is equal to the first size. As an example, in an embodiment of the present disclosure, both the first size and the second size are 10 nm.

In the present disclosure, the surface area of the first active area Act1 exposed by the bitline contact groove BLGR is a first area when the pit BLPIT is not provided, and is a second area after the pit BLPIT is provided. That is, when the bitline contact groove BLGR is formed on the semiconductor substrate BP, the surface area of the first active area Act1 exposed by the bitline contact groove BLGR is the first area. After the etch stop layer ESL is removed, the surface area of the first active area Act1 exposed by the bitline contact groove BLGR and the pit BLPIT is the second area.

In some embodiments, the second area is 2 to 4 times of the first area. In this way, the contact area between the bitline lead BLL and the first active area Act1 may be significantly increased, such that the performance of the semiconductor structure may be significantly improved.

In some embodiments of the present disclosure, in Step S140, the exposed first active area Act1 may be selectively etched by using a first etching condition. Further, under the first etching condition, an etching rate of the first active area Act1 is 10 times more than that of the etch stop layer ESL. Further, the etching rate of the first active area Act1 is 10 to 20 times more than that of the etch stop layer ESL.

In an embodiment of the present disclosure, the first etching condition refers to selectively etching the exposed first active area Act1 by dry etching. During the dry etching process, the etch stop layer ESL is positioned on the sidewall of the bitline contact groove BLGR and thus has a lower etching rate, such that higher etching selectivity is formed between the first active area Act1 and the etch stop layer ESL.

In an embodiment of the present disclosure, the first etching condition refers to etching the first active area Act1 by using a gas including hydrogen bromide.

In Step S150, referring to FIG. 12, the etch stop layer ESL may be removed. In this way, the bitline contact groove BLGR may be completely exposed again, to form the bitline structure BL. In some embodiments, the etch stop layer ESL may be selectively etched by using a second etching condition. Further, under the second etching condition, the etching rate of the etch stop layer ESL is 30 times more than that of the first active area Act1. Further, the etching rate of the etch stop layer being 30 to 50 times more than that of the first active area Act1.

In an embodiment of the present disclosure, the second etching condition refers to etching the etch stop layer ESL by using an acid etching liquid including an oxidant. As an example, in an embodiment, the etching liquid may include sulfuric acid and hydrogen peroxide.

In Step S160, a bitline structure BL may be formed, where the bitline lead BLL of the bitline structure BL fills up the pit BLPIT. In this way, the contact area between the bitline lead BLL and the recessed transistor may be increased, the data writing or reading speed may be increased, and thus the performance of the semiconductor structure may be improved.

In some embodiments, the step of forming a bitline structure BL may include Steps S410 to S440.

Step S410, as shown in FIG. 15, forming a polysilicon filling material layer BLL10, the polysilicon filling material layer BLL10 filling up the bitline contact groove BLGR and the pit BLPIT;

Step S420, as shown in FIG. 16, sequentially forming a bitline conductive material layer BLL20 covering the polysilicon filling material layer BLL10 and a bitline insulation cap material layer BLL30;

Step S430, as shown in FIG. 18, patterning the polysilicon filling material layer BLL10, the bitline conductive material layer BLL20 and the bitline insulation cap material layer BLL30 to form the bitline lead BLL filling up the pit BLPIT; and

Step S440, as shown in FIG. 23, forming an insulation filling layer BLF filling up the bitline contact groove BLGR and a bitline insulation layer BLD covering the bitline lead BLL.

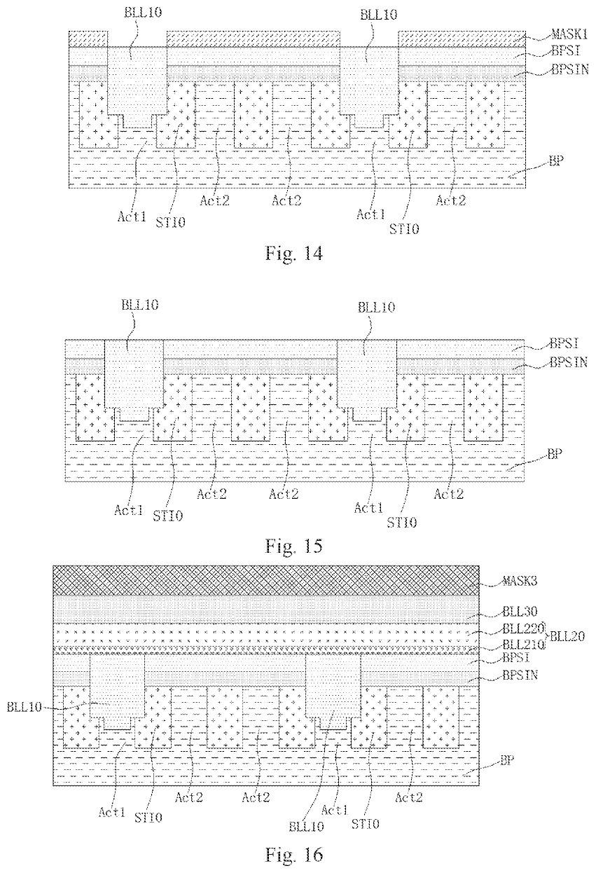

In some embodiments, in Step S410, as shown in FIG. 13, polysilicon may be first deposited on the surface of the base substrate to form an initial polysilicon filling material layer BLL10, where the initial polysilicon filling material layer BLL10 fills up the bitline contact groove BLGR and the pit BLPIT, and covers the first mask layer MASK1. It is to be understood that after the deposition, the initial polysilicon filling material layer BLL10 may be planarized by a planarization process such as chemical mechanical polishing (CMP). Next, referring to FIG. 14, the initial polysilicon filling material layer BLL10 is etched back (etched) to expose the first mask layer MASK1. Because the polysilicon and the first mask layer MASK1 are different in etch rate, the initial polysilicon filling material layer BLL10 may be etched back to be substantially flush with the substrate etching positioning layer BPSI, to form the desired polysilicon filling material layer BLL10. Next, referring to FIG. 15, the first mask layer MASK1 may be removed to reduce a thickness of the semiconductor structure. In this way, the polysilicon filling material layer BLL10 and the substrate etching positioning layer BPSI are substantially flush and embedded with each other. In an embodiment of the present disclosure, a material of the polysilicon filling material layer BLL10 and a material of the substrate etching positioning layer BPSI both are polysilicon, such that the polysilicon filling material layer BLL10 and the substrate etching positioning layer BPSI are embedded with each other to form a film layer made of the same material.

In some embodiments, in Step S410, the polysilicon filling material layer BLL10 may also be crystallized to eliminate defects of the polysilicon filling material layer BLL10 and improve electrical stability and electrical conductivity of the polysilicon filling material layer BLL10. It is to be understood that in the process of crystallizing the polysilicon filling material layer BLL10, the substrate etching positioning layer BPSI made of polysilicon may also be crystallized.

In Step S420, referring to FIG. 16, a bitline conductive material layer BLL20 and a bitline insulation cap material layer BLL30 may be sequentially formed on the base substrate, where the bitline conductive material layer BLL20 and the bitline insulation cap material layer BLL30 cover the polysilicon filling material layer BLL10.

Referring to FIG. 16, the bitline conductive material layer BLL20 and the bitline insulation cap material layer BLL30 may be formed by a deposition method. The bitline conductive material layer BLL20 and the bitline insulation cap material layer BLL30 both are material layers having a whole plane, to completely cover the polysilicon filling material layers BLL10 and regions between the polysilicon filling material layers BLL10. In an embodiment of the present disclosure, the bitline conductive material layer BLL20 covers the polysilicon filling material layer BLL10 and the substrate etching positioning layer BPSI; and the bitline insulation cap material layer BLL30 covers the bitline conductive material layer BLL20.

In the present disclosure, the bitline conductive material layer BLL20 may include a layer of conductive material layer, or may include multilayer conductive material layers stacked up. For example, in an embodiment of the present disclosure, the bitline conductive material layer BLL20 includes a bitline first conductive material layer BLL210 and a bitline second conductive material layer BLL220 positioned on a side of the bitline first conductive material layer BLL210 away from the semiconductor substrate BP. A material of the bitline first conductive material layer BLL210 may be different from that of the bitline second conductive material layer BLL220. Further, the material of the bitline first conductive material layer BLL210 may be titanium nitride, and the material of the bitline second conductive material layer BLL220 may be tungsten.

In the present disclosure, the bitline insulation cap material layer BLL30 may include a layer of inorganic insulation material layer or multilayer inorganic insulation material layers stacked up. For example, in an embodiment of the present disclosure, the bitline insulation cap material layer BLL30 may be a silicon nitride layer.

In Step S430, the polysilicon filling material layer BLL10, the bitline conductive material layer BLL20 and the bitline insulation cap material layer BLL30 are patterned to form the bitline lead BLL, where the bitline lead BLL fills up the pit BLPIT.

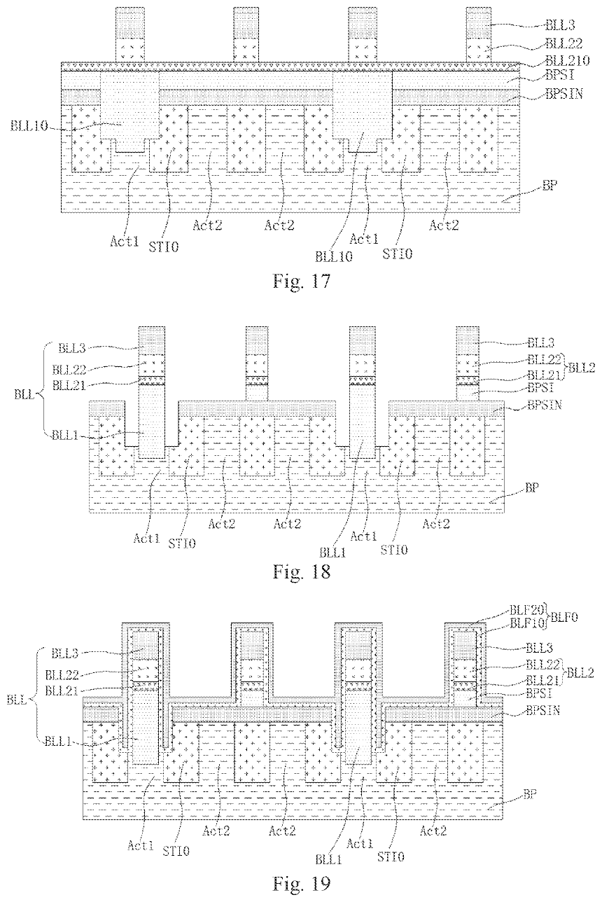

In an embodiment of the present disclosure, Step S430 may include following processes. Referring to FIG. 16, a third mask layer MASK3 is formed on the bitline insulation cap material layer BLL30. As shown in FIG. 17 and FIG. 18, the polysilicon filling material layer BLL10, the bitline conductive material layer BLL20 and the bitline insulation cap material layer BLL30 are patterned by using the third mask layer MASK3 as a mask.

Further, the bitline insulation cap material layer BLL30 and the bitline second conductive material layer BLL220 may be patterned first to form the bitline insulation cap layer BLL3 and the bitline second conductive layer BLL22 respectively. Next, the bitline first conductive material layer BLL210 and the polysilicon filling material layer BLL10 are patterned by using the bitline second conductive layer BLL22 and the bitline insulation cap layer BLL3 as masks, to form the bitline first conductive layer BLL21 and the polysilicon filling layer BLL1 respectively.

In some embodiments, referring to FIG. 18, when the material of the polysilicon filling material layer BLL10 and the material of the substrate etching positioning layer BPSI are both polysilicon, the substrate etching positioning layer BPSI may also be patterned. Thus, at the part of the bitline lead BLL overlapped with the bitline contact groove BLGR, the bitline lead BLL may include the polysilicon filling layer BLL1, the bitline conductive layer BLL2 and the bitline insulation cap layer BLL3 that are sequentially stacked and patterned. At the part of the bitline lead BLL not overlapped with the bitline contact groove BLGR, the bitline lead BLL may include the substrate etching positioning layer BPSI, the bitline conductive layer BLL2 and the bitline insulation cap layer BLL3 that are sequentially stacked and patterned.

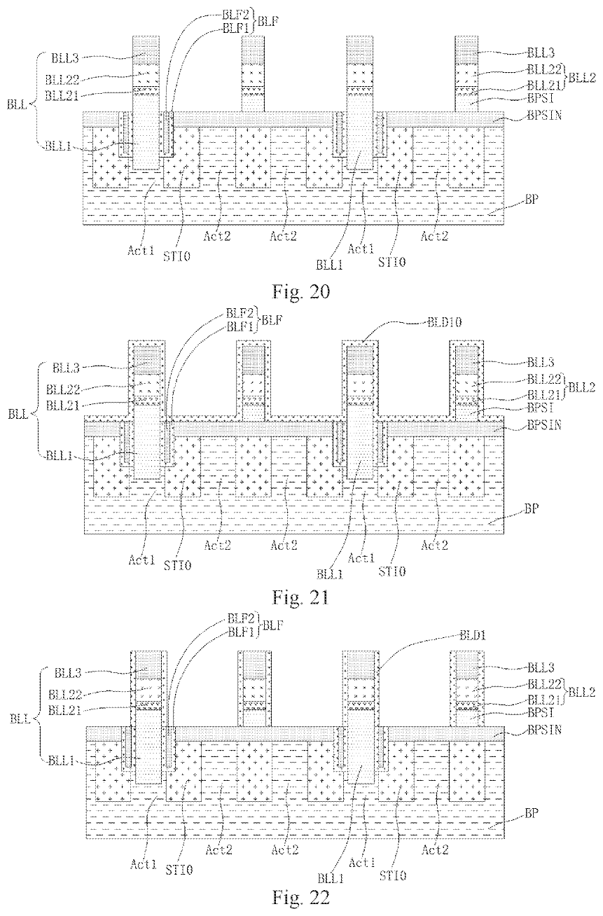

In Step S440, as shown in FIG. 20 and FIG. 23, the insulation filling layer BLF filling the bitline contact groove BLGR may be formed first, and then the bitline insulation layer BLD covering the bitline lead BLL is formed.

In some embodiments, the insulation filling layer BLF filling the bitline contact groove BLGR may be formed by the following steps. As shown in FIG. 19, an insulation filling material is deposited on the surface of the base substrate to form the insulation filling material layer BLF0 covering the entire base substrate. As shown in FIG. 20, the insulation filling material layer BLF0 is patterned to form the insulation filling layer BLF, and the insulation filling layer BLF may only fill up the bitline contact groove BLGR. Of course, in other embodiments of the present disclosure, a part of the film layer remained after the insulation filling material layer BLF0 is patterned may also be used as other functional film layers other than the insulation filling layer BLF and positioned outside the bitline contact groove BLGR.

In some embodiments, the insulation filling material layer BLF0 may include a filling material, or may include various different filling materials. For example, in an embodiment of the present disclosure, the insulation filling material layer BLF0 may include an insulation first filling material layer BLF10 and an insulation second filling material layer BLF20 arranged in sequence, where the insulation second filling material layer BLF20 is positioned on a side of the insulation first filling material layer BLF10 away from the semiconductor substrate BP. After the insulation first filling material layer BLF10 and the insulation second filling material layer BLF20 are patterned, an insulation first filling layer BLF1 and an insulation second filling layer BLF2 are respectively formed. The insulation first filling layer BLF1 may be in close contact with a sidewall of the bitline contact groove BLGR and a sidewall of the polysilicon filling layer BLL1. In one bitline contact groove BLGR, the insulation second filling layer BLF2 is filled into a gap between the insulation first filling layers BLF1. Further, a material of the insulation first filling material layer BLF10 is silicon oxide; and a material of the insulation second filling material layer BLF20 is silicon nitride.

For another example, in another embodiment of the present disclosure, the insulation filling material layer BLF0 may include a silicon nitride layer (not shown in FIG. 19, etc.), the insulation first filling material layer BLF10 and the insulation second filling material layer BLF20 that are sequentially stacked on the base substrate, where the silicon nitride layer covers the surface of the base substrate, including but not limited to the surface of the bitline lead BL and the surface of the bitline contact groove. When patterning the insulation filling material layer BLF0, the insulation first filling material layer BLF10 and the insulation second filling material layer BLF20 may be patterned without patterning the silicon nitride layer. In this way, in the insulation filling layer BLF formed, the silicon nitride layer can keep covering and protecting the sidewall and a top surface of the bitline lead.

In some embodiments, the bitline insulation layer BLD covering the bitline lead BLL may be formed by the following steps. As shown in FIG. 21, a bitline first insulation material layer BLD10 is formed on the surface of the base substrate, and the bitline first insulation material layer BLD10 covers the bitline lead BLL. As shown in FIG. 22, the bitline first insulation material layer BLD10 is patterned to form a bitline first insulation layer BLD1, where the bitline first insulation layer BLD1 only covers the sidewall of the bitline lead BLL. As shown in FIG. 23, a bitline second insulation layer BLD2 is formed on the surface of the base substrate. Thus, the bitline second insulation layer BLD2 and the bitline first insulation layer BLD1 constitute the bitline insulation layer BLD of the present disclosure. The sidewall of the bitline lead BLL is sequentially protected by the bitline first insulation layer BLD1 and the bitline second insulation layer BLD2, and a top of the bitline lead BLL is protected by the bitline second insulation layer BLD2. Referring to FIG. 23, a part between adjacent bitline structures BL may also be provided with the bitline insulation layer BLD. For example, the bitline second insulation layer BLD2 may also cover between the adjacent bitline structures BL.

In an embodiment of the present disclosure, a material of the bitline second insulation layer BLD2 may be the same as that of the bitline insulation cap layer BLL3, such that good binding is provided between the bitline insulation cap layer BLL3 and the bitline second insulation layer BLD2, thereby improving an insulation effect of the bitline structure BL. Further, the material of the bitline second insulation layer BLD2 and the material of the bitline insulation cap layer BLL3 are both silicon nitride.

In an embodiment of the present disclosure, a material of the bitline first insulation layer BLD1 is silicon oxide. The material of the bitline second insulation layer BLD2 is silicon nitride.

It is to be understood that the bitline insulation layer BLD may also be made from other inorganic insulation materials, or may have other film layer structures, which is not limited in the present disclosure.

In Step S170, the conductive plug PLUG may be formed by following steps.

Step S510, as shown in FIG. 24, forming a plug hole HOLE0 exposing the second active area Act2; and

Step S520, as shown in FIG. 25, filling the plug hole HOLE0 with polysilicon to form the conductive plug PLUG.

In Step S510, referring to FIG. 24, the base substrate may be patterned to form the plug hole HOLE0 exposing the second active area Act2. The plug hole HOLE0 neither overlaps with the first active area Act1 nor overlaps with the bitline structure BL.

In Step S520, polysilicon may be filled in the plug hole HOLE0 by deposition to form the conductive plug PLUG. In this way, the conductive plug PLUG may serve as a conductive terminal electrically connected to the second active area Act2, such that the second active area Act2 may be electrically connected to other devices of the semiconductor structure. Further, referring to FIG. 25, the conductive plug PLUG is completely positioned in the plug hole HOLE0, but does not fill up the plug hole HOLE0. That is, a top surface of the conductive plug PLUG is lower than a top of the bitline structure BL.

In an embodiment of the present disclosure, the conductive plug PLUG is electrically connected to the plurality of transfer electrodes, and the plurality of transfer electrodes may be electrically connected to other functional devices. When the conductive plug PLUG is electrically connected to capacitors or the like used as the functional devices by means of the plurality of transfer electrodes, the semiconductor structure may be a memory apparatus. For example, after the conductive plug PLUG is formed, the method for fabricating a semiconductor structure provided by the present disclosure further includes: forming a transfer electrode layer on a side of the conductive plug PLUG away from the semiconductor substrate BP, the transfer electrode layer comprising a plurality of transfer electrodes electrically connected to the conductive plugs PLUG in one-to-one correspondence; and forming a device layer on a side of the transfer electrode layer away from the semiconductor substrate BP, the device layer comprising a plurality of functional devices electrically connected to the plurality of transfer electrodes in one-to-one correspondence.

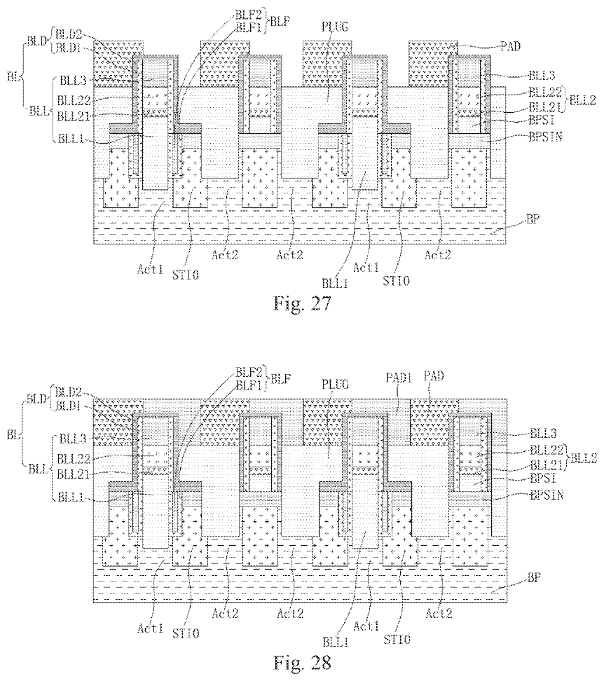

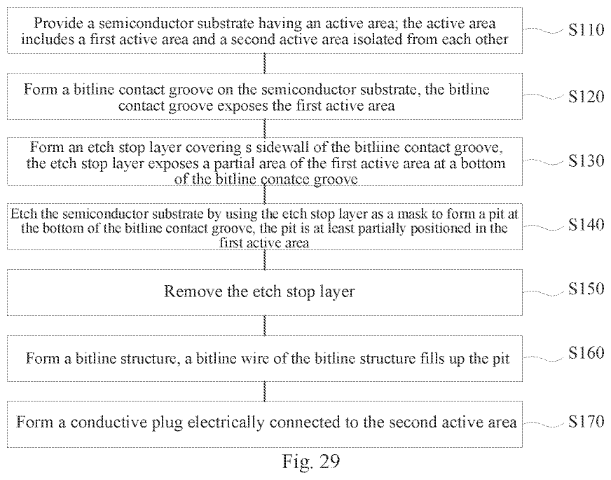

In an embodiment of the present disclosure, the transfer electrode layer may be formed by following steps. Referring to FIG. 26, an electrode material layer PAD0 may be formed on the base substrate, where the electrode material layer PAD0 fills up the plug hole HOLE0 and is electrically connected to the conductive plug PLUG, and covers the bitline structure BL. Referring to FIG. 27, the electrode material layer PAD0 may be patterned to form the plurality of array-distributed transfer electrodes PAD. One of the plurality of transfer electrodes PAD is electrically connected to one of the conductive plugs PLUG. Referring to FIG. 28, in a gap between the plurality of transfer electrodes PAD, an insulation spacer material may be filled to form an isolation material layer PAD1. Further, a material of the isolation material layer PAD1 may be silicon nitride.

Correspondingly, the semiconductor structure further includes: a transfer electrode layer positioned on a side of the conductive plug away from the semiconductor substrate, where the transfer electrode layer includes a plurality of transfer electrodes electrically connected to the conductive plugs in one-to-one correspondence; and

a device layer positioned on a side of the transfer electrode layer away from the semiconductor substrate, the device layer including a plurality of functional devices electrically connected to the plurality of transfer electrodes in one-to-one correspondence.

It is to be noted that steps of the method for fabricating a semiconductor structure in the present disclosure are described in a particular order in the accompanying drawings. However, this does not require or imply to execute these steps necessarily according to the particular order, or this does not mean that the expected result cannot be implemented unless all the shown steps are executed. Additionally, some steps may be omitted, a plurality of steps may be combined into one step for execution, and/or one step may be decomposed into a plurality of steps for execution.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the appended claims.

### INDUSTRIAL APPLICABILITY

An embodiment of the present disclosure provides a method for fabricating a semiconductor structure, including: providing a semiconductor substrate having an active area, the active area including a first active area and a second active area isolated from each other; forming a bitline contact groove on the semiconductor substrate, the bitline contact groove exposing the first active area; forming an etch stop layer covering a sidewall of the bitline contact groove, the etch stop layer exposing a partial area of the first active area at a bottom of the bitline contact groove; etching the semiconductor substrate by using the etch stop layer as a mask to form a pit at the bottom of the bitline contact groove, the pit being at least partially positioned in the first active area; removing the etch stop layer; forming a bitline structure, a bitline lead of the bitline structure filling up the pit; and forming a conductive plug electrically connected to the second active area. According to the method for fabricating a semiconductor structure provided by the present disclosure, after the bitline contact groove is formed, a pit is also formed at the bottom of the bitline contact groove. When forming a bitline lead, the bitline lead may fill up the pit, to increase a contact area between the bitline lead and the first active area, and increase speed of charge transfer between the bitline lead and the first active area, such that limitations of the speed of charge transfer on the semiconductor structure can be avoided, and thus performance of a semiconductor device can be improved.

What is claimed is:

1. A method for fabricating a semiconductor structure, comprising:
providing a semiconductor substrate having an active area; the active area comprising a first active area and a second active area isolated from each other;
forming a bitline contact groove on the semiconductor substrate, the bitline contact groove exposing the first active area;
forming an etch stop layer covering a sidewall of the bitline contact groove, the etch stop layer exposing a partial area of the first active area at a bottom of the bitline contact groove;
etching the semiconductor substrate by using the etch stop layer as a mask to form a pit at the bottom of the bitline contact groove, the pit being at least partially positioned in the first active area;
removing the etch stop layer;
forming a bitline structure, a bitline lead of the bitline structure filling up the pit; and
forming a conductive plug, the conductive plug being electrically connected to the second active area.

2. The method for fabricating a semiconductor structure according to claim 1, wherein the forming a bitline contact groove on the semiconductor substrate comprises:
forming a first mask layer on the semiconductor substrate, the first mask layer covering the second active area and exposing the first active area; and
patterning the semiconductor substrate by using the first mask layer as a mask to form the bitline contact groove exposing the first active area.

3. The method for fabricating a semiconductor structure according to claim 2, wherein the forming an etch stop layer covering a sidewall of the bitline contact groove comprises:
forming an etch stop material layer covering a surface of the first mask layer, the sidewall of the bitline contact groove and the bottom of the bitline contact groove, a part of the etch stop material layer at the bottom of the bitline contact groove being at least partially overlapped with the first active area; and
patterning the etch stop material layer to remove the part of the etch stop material layer positioned at the bottom of the bitline contact groove, to form the etch stop layer covering the sidewall of the bitline contact groove.

4. The method for fabricating a semiconductor structure according to claim 3, wherein a material of the etch stop material layer is titanium nitride.

5. The method for fabricating a semiconductor structure according to claim 3, wherein the etch stop material layer is formed by atomic layer deposition.

6. The method for fabricating a semiconductor structure according to claim 3, wherein the etch stop material layer is patterned by dry etching.

7. The method for fabricating a semiconductor structure according to claim 1, wherein the etching the semiconductor substrate by using the etch stop layer as a mask comprises:
etching the exposed first active area of the semiconductor substrate by using a first etching condition, under the first etching condition, an etching rate of the first active area being 10 times more than an etching rate of the etch stop layer.

8. The method for fabricating a semiconductor structure according to claim 7, wherein the first etching condition refers to etching the first active area by using a gas including hydrogen bromide.

9. The method for fabricating a semiconductor structure according to claim 1, wherein the semiconductor substrate is buried with a wordline structure, a size of the bitline lead along an extension direction of the wordline structure being a first size, and a depth of the pit being a second size; and
wherein the second size is 0.5 to 2 times of the first size.

10. The method for fabricating a semiconductor structure according to claim 1, wherein the removing the etch stop layer comprises:
etching the etch stop layer by using a second etching condition, under the second etching condition, an etching rate of the etch stop layer being 30 times more than an etching rate of the first active area.

11. The method for fabricating a semiconductor structure according to claim 10, wherein the second etching condition refers to etching the etch stop layer by using an acid etching liquid including an oxidant.

12. The method for fabricating a semiconductor structure according to claim 1, wherein when forming a bitline contact groove on the semiconductor substrate, a surface area of the first active area exposed by the bitline contact groove is a first area;
after the etch stop layer is removed, a surface area of the first active area exposed by the bitline contact groove and the pit is a second area; and
the second area is 2 to 4 times of the first area.

13. The method for fabricating a semiconductor structure according to claim 1, wherein the forming a bitline structure comprises:
forming a polysilicon filling material layer, the polysilicon filling material layer filling up the bitline contact groove and the pit;
sequentially forming a bitline conductive material layer and a bitline insulation cap material layer covering the polysilicon filling material layer;
patterning the polysilicon filling material layer, the bitline conductive material layer and the bitline insulation cap material layer to form the bitline lead filling up the pit; and
forming an insulation filling layer filling up the bitline contact groove and a bitline insulation layer covering the bitline lead.

14. The method for fabricating a semiconductor structure according to claim 1, wherein the forming a conductive plug comprises:
forming a plug hole exposing the second active area; and
filling polysilicon into the plug hole to form the conductive plug.

15. The method for fabricating a semiconductor structure according to claim 1, further comprising:
forming a transfer electrode layer on a side of the conductive plug away from the semiconductor substrate, the transfer electrode layer comprising a plurality of transfer electrodes electrically connected to the conductive plugs in one-to-one correspondence; and
forming a device layer on a side of the transfer electrode layer away from the semiconductor substrate, the device layer comprising a plurality of functional devices electrically connected to the plurality of transfer electrodes in one-to-one correspondence.

16. A semiconductor structure comprising a semiconductor substrate, a bitline structure and a conductive plug; wherein the semiconductor substrate has an active area; the active area comprises a first active area and a second active area isolated from each other; the semiconductor substrate is provided with a bitline contact groove overlapped with the first active area, and a pit at least partially positioned in the first active area is provided at a bottom of the bitline contact groove; the bitline structure comprises a bitline lead configured for electric conduction, the bitline lead fills up the pit and is electrically connected to the first active area in the bitline contact groove; and the conductive plug is electrically connected to the second active area.

17. The semiconductor structure according to claim 16, wherein a depth of the bitline contact groove is 3 to 4 times of a depth of the pit.

18. The semiconductor structure according to claim 16, wherein the semiconductor substrate is buried with a wordline structure; a size of the bitline lead along an extension direction of the wordline structure is a first size, and the depth of the pit is a second size; and
the second size is 0.5 to 2 times of the first size.

19. The semiconductor structure according to claim 16, further comprising:
a transfer electrode layer positioned on a side of the conductive plug away from the semiconductor substrate, the transfer electrode layer comprising a plurality of transfer electrodes electrically connected to the conductive plugs in one-to-one correspondence; and
a device layer positioned on a side of the transfer electrode layer away from the semiconductor substrate, the device layer comprising a plurality of functional devices electrically connected to the plurality of transfer electrodes in one-to-one correspondence.
